(19) United States
(12) Patent Application Publication
(10) Pub. No.: US 2025/0185430 A1
(43) Pub. Date: Jun. 5, 2025

(54) STRETCHABLE PANEL AND ELECTRONIC DEVICE

(71) Applicant: Samsung Electronics Co., Ltd., Suwon-si (KR)

(72) Inventors: Gae Hwang LEE, Suwon-si (KR); Hyun Bum KANG, Suwon-si (KR); Hyung Jun KIM, Suwon-si (KR)

(73) Assignee: Samsung Electronics Co., Ltd., Suwon-si (KR)

(21) Appl. No.: 18/909,412

(22) Filed: Oct. 8, 2024

(30) Foreign Application Priority Data
Dec. 1, 2023 (KR) 10-2023-0172667
Oct. 2, 2024 (KR) 10-2024-0133993

(51) Int. Cl. H01L 33/62; H01L 25/16; H01L 27/12

(52) U.S. Cl. CPC H10H 20/857; H01L 25/167; H10D 86/443; H10D 86/60

(57) ABSTRACT

Disclosed are a stretchable panel and an electronic device including the same, the stretchable panel including a stretchable substrate, and a wire electrode on the stretchable substrate, wherein the wire electrode includes a first conductive layer including a first conductor, an clastic layer, and a second conductive layer disposed on the clastic layer and including a second conductor.

### CROSS-REFERENCE TO RELATED APPLICATION

This application claims priority to and the benefit of Korean Patent Application No. 10-2023-0172667 filed in the Korean Intellectual Property Office on Dec. 1, 2023, and Korean Patent Application No. 10-2024-0133993 filed in the Korean Intellectual Property Office on Oct. 2, 2024, the entire contents of which are incorporated herein by reference.

### BACKGROUND OF THE INVENTION

### (a) Field of the Invention

A stretchable panel and an electronic device are related.

### (b) Description of the Related Art

In recent years, research on a stretchable panel such as a display panel that can be curved, bent, or folded or a wearable sensor array that are attached to a living body or an object is in progress. Such a stretchable panel may need to have stretchability of being stretched or restored according to motions of the living body or shapes of the object as well as the flexibility of being curved, bent, or folded in a predetermined direction.

### SUMMARY OF THE INVENTION

However, even if a stretchable panel has flexibility and stretchability, stress may be concentrated in a specific region during stretching, and structural and functional deformation and damage may occur in the region where such stress is concentrated, thereby reducing electrical performance.

Some example embodiments provide a stretchable panel that may reduce or prevent degradation of electrical performance while ensuring flexibility and stretchability.

Some example embodiments provide an electronic device including the stretchable panel.

According to some example embodiments, a stretchable panel includes stretchable substrate, and a wire electrode on the stretchable substrate, the wire electrode including a first conductive layer including a first conductor, an elastic layer, and a second conductive layer on the elastic layer and including a second conductor.

The elastic layer may include an elastomer and the second conductor.

The second conductor included in the elastic layer may be unevenly distributed along a thickness direction of the elastic layer.

The elastic layer may include a first region relatively close to the second conductive layer and a second region relatively distant from the second conductive layer along the thickness direction of the elastic layer, wherein a distribution of the second conductor included in the first region may be greater than a distribution of the second conductor included in the second region.

The first conductive layer and the second conductive layer may be electrically connected.

The stretchable panel may further include a non-stretchable pattern covering a portion of the stretchable substrate and having a higher elastic modulus than the stretchable substrate, a plurality of unit elements on the non-stretchable pattern, and a plurality of pixel circuits configured to independently operate the plurality of unit elements.

The non-stretchable pattern may include a plurality of planar patterns repeatedly arranged on the stretchable substrate and on which the plurality of unit elements are arranged, and a plurality of bridge patterns connecting adjacent planar patterns, and the wire electrodes may be on the plurality of planar patterns and the plurality of bridge patterns.

The wire electrode may electrically connect the plurality of unit elements and/or electrically connect the unit elements and the pixel circuits.

The non-stretchable pattern may include a plurality of island-shaped patterns repeatedly arranged on the stretchable substrate and separated from each other, each of the plurality of unit elements is on a respective one of the plurality of island-shaped patterns, and the wire electrode electrically connects adjacent unit elements of the plurality of unit elements between adjacent ones of the plurality of island-shaped patterns.

The stretchable panel may further include a non-stretchable layer positioned at least one of under the wire electrode or on the wire electrode.

The non-stretchable pattern may include polycarbonate, polymethyl methacrylate, polyethylene terephthalate, polyethylene naphthalate, polyimide, polyamide, polyamidoimide, polyethersulfone, or a combination thereof.

The plurality of unit elements may include a light emitting diode, a photoelectric conversion diode, or a combination thereof.

The plurality of pixel circuits may include a first pixel circuit and a second pixel circuit for each of the plurality of unit elements, the first pixel circuit may be on the non-stretchable pattern, and the second pixel circuit may be on the stretchable substrate that is not covered by the non-stretchable pattern.

The first conductive layer, the elastic layer, and the second conductive layer may be sequentially stacked from the stretchable substrate.

A width of the second conductive layer may be greater than a width of the elastic layer.

At least a portion of the second conductive layer may be in direct contact with the first conductive layer.

The elastic layer, the second conductive layer, and the first conductive layer may be sequentially stacked from the stretchable substrate.

The first conductor and the second conductor may each independently include silver (Ag), gold (Au), copper (Cu), aluminum (Al), nickel (Ni), molybdenum (Mo), an alloy thereof, and/or a combination thereof.

The elastic layer may include at least one of polyorganosiloxane, a polymer including a butadiene structural unit, a polymer including an olefin structural unit, a polymer including a urethane structural unit, a polymer including an acrylic structural unit, or a combination thereof.

According to some example embodiments, a stretchable panel includes a stretchable substrate, and a wire electrode on the stretchable substrate and including a first conductive layer, an elastic layer, and a second conductive layer electrically connected to the first conductive layer.

The elastic layer may be between the first conductive layer and the second conductive layer.

The elastic layer may include a second conductor, and the first conductive layer and the second conductive layer may be electrically connected through the conductor.

The second conductor layer may include the second conductive.

The second conductive layer may be between the first conductive layer and the elastic layer.

The second conductive layer and the first conductive layer may be in direct contact with each other.

According to some example embodiments, an electronic device including the stretchable panel is provided.

It is possible to reduce or prevent degradation of electrical performance while ensuring the flexibility and stretchability of the stretchable panel.

### BRIEF DESCRIPTION OF THE DRAWINGS

FIG. 1 is a plan view schematically showing an example of a stretchable panel according to some example embodiments,

FIG. 2 is a plan view according to an example showing an enlarged portion “A” of the stretchable panel of FIG. 1,

FIGS. 3 to 11 are cross-sectional views showing various examples of wire electrodes taken along line III-III of FIG. 1,

FIG. 12 is a plan view of a stretchable panel according to another example, showing an enlarged portion of “A” in FIG. 1,

FIG. 13 is a cross-sectional view of an example of the stretchable panel of FIG. 12,

FIG. 14 is a cross-sectional view showing an example of a unit element,

FIG. 15 is a plan view schematically showing an example of a stretchable panel according to some example embodiments,

FIG. 16 is a plan view showing an example of the arrangement of the non-stretchable pattern 110b in the stretchable panel of FIG. 15,

FIG. 17 is a cross-sectional view showing an example of a wire electrode in the stretchable panel of FIG. 15,

FIG. 18 is a schematic view showing a skin-type stretchable display panel according to an example,

FIGS. 19 to 22 are schematic views showing examples of stretchable display panels according to one example, respectively,

FIGS. 23A-23C are schematic views showing a skin-type sensor array according to an example,

FIG. 24 is a graph showing electrical conductivity of electrodes according to examples and reference examples, and

FIG. 25 is a graph showing electrical characteristics according to stretching of electrodes according to examples and reference examples.

### DETAILED DESCRIPTION OF THE EMBODIMENTS

Hereinafter, the embodiments will be described in detail so that those of ordinary skill in the art can easily implement them. However, the actually applied structure may be implemented in several different forms and is not limited to the embodiments described herein.

In the drawings, the thickness of layers, films, panels, regions, etc., may be exaggerated for clarity. Additionally, when the terms “about” or “substantially” are used in this specification in connection with a numerical value and/or geometric terms, it is intended that the associated numerical value includes a manufacturing tolerance (e.g., +10%) around the stated numerical value. Further, regardless of whether numerical values and/or geometric terms are modified as “about” or “substantially,” it will be understood that these values should be construed as including a manufacturing or operational tolerance (e.g., +10%) around the stated numerical values and/or geometry. Additionally, whenever a range of values is enumerated, the range includes all values within the range as if recorded explicitly clearly, and may further include the boundaries of the range. Accordingly, the range of “X” to “Y” includes all values between X and Y, including X and Y.

It will be understood that when an element such as a layer, film, region, or substrate is referred to as being “on” another element, it may be directly on the other element or intervening elements may also be present. In contrast, when an element is referred to as being “directly on” another element, there are no intervening elements present. It will also be understood that such spatially relative terms, such as “above”, “top”, etc., are intended to encompass different orientations of the device in use or operation in addition to the orientation depicted in the figures, and that the device may be otherwise oriented (rotated 90 degrees or at other orientations) and the spatially relative terms used herein interpreted accordingly.

As used herein, when a definition is not otherwise provided, “substituted” refers to replacement of hydrogen of a compound or a functional group by a substituent selected from a halogen atom, a hydroxy group, an alkoxy group, a nitro group, a cyano group, an amino group, an azido group, an amidino group, a hydrazino group, a hydrazono group, a carbonyl group, a carbamyl group, a thiol group, an ester group, a carboxyl group or a salt thereof, sulfonic acid group or a salt thereof, a phosphoric acid group or a salt thereof, a silyl group, a C1 to C20 alkyl group, a C2 to C20 alkenyl group, a C2 to C20 alkynyl group, a C6 to C30 aryl group, C7 to C30 arylalkyl group, C1 to C30 alkoxy group, a C1 to C20 heteroalkyl group, a C3 to C20 heteroaryl group, C3 to C20 heteroarylalkyl group, a C3 to C30 cycloalkyl group, a C3 to C15 cycloalkenyl group, a C6 to C15 cycloalkynyl group, a C3 to C30 heterocycloalkyl group, and any combination thereof.

Hereinafter, “polymer” includes a homopolymer, a copolymer, and/and/or a combination thereof.

Hereinafter, “combination” includes a mixture, a composite, or a stacked structure of two or more.

Hereinafter, an example of a stretchable panel according to some example embodiments will be described with reference to the drawings.

A stretchable panel according to some example embodiments may include a panel f and/or an electronic device in which an element array including a plurality of unit elements is arranged on a stretchable substrate deformable by an external force, and may include, for example, a flexible display panel, a stretchable display panel, a flexible sensor array panel, a stretchable sensor array panel, and/or a combination thereof having flexible and/or stretchable characteristics.

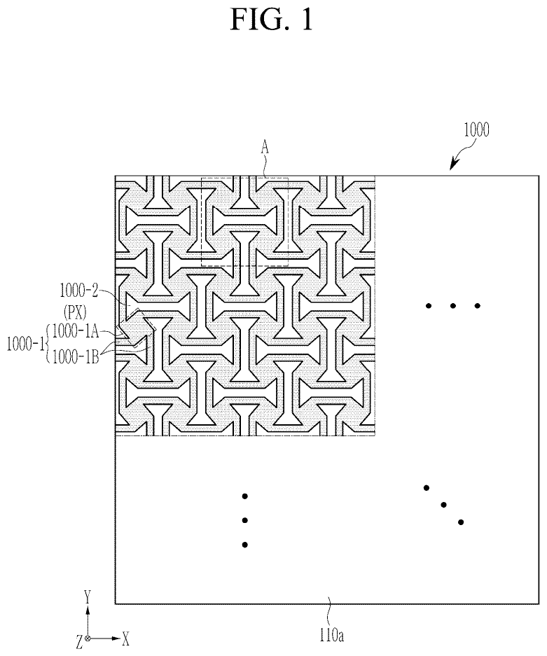

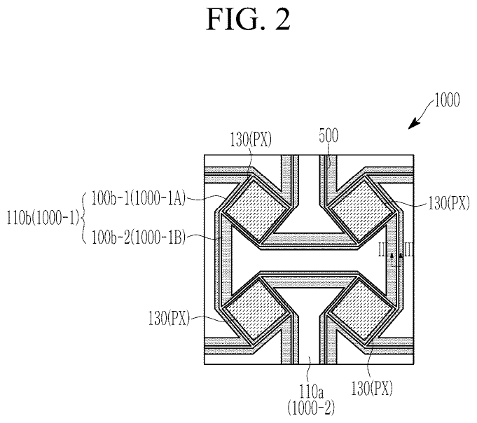

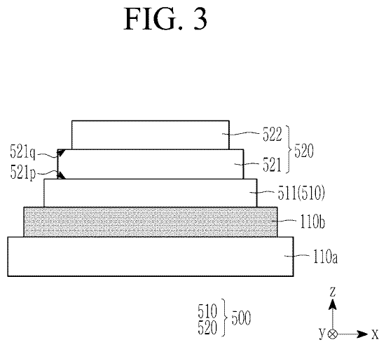

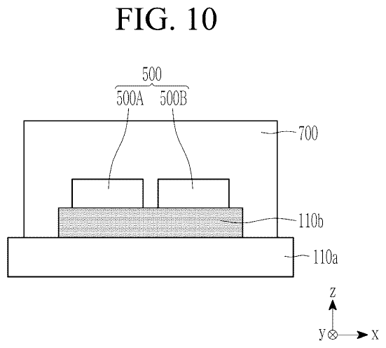

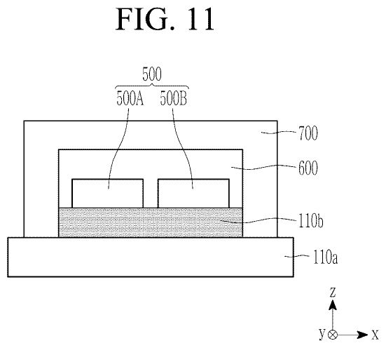

FIG. 1 is a plan view schematically showing an example of a stretchable panel according to some example embodiments, FIG. 2 is a plan view according to an example showing an enlarged portion “A” of the stretchable panel of FIG. 1, and FIGS. 3 to 11 are cross-sectional views showing various examples of wire electrodes taken along line III-III of FIG. 1.

Referring to FIGS. 1 and 2, the stretchable panel 1000 according to some example embodiments includes regions where the elastic modulus are different along an in-plane direction (e.g., X-Y directions) of the stretchable substrate 110a, and includes a stretchable region 1000-2 where the elastic modulus is relatively low and a non-stretchable region 1000-1 where the elastic modulus is relatively high.

The stretchable region 1000-2 is a region configured to flexibly respond to an external force such as twisting, pressing, and pulling, and may be a region excluding the non-stretchable region 1000-1. For example, the stretchable region 1000-2 may be configured to have a larger elastic deformation profile compared to, e.g., the non-stretchable region 1000-1. In at least some embodiments, the stretchable region 1000-2 may be a region in which the non-stretchable pattern 110b is not covered on the stretchable substrate 110a and may be relatively evenly disposed on the whole surface of the stretchable panel 1000.

The elastic modulus of the stretchable region 1000-2 may be substantially the same as the elastic modulus of the stretchable substrate 110a. The stretchable substrate 110a may include an elastomer with a relatively low elastic modulus, for example, an elastomer (including organic and inorganic elastomer), an inorganic elastomer-like material, and/or a combination thereof.

The elastomer may include for example polyorganosiloxane, a polymer including a butadiene structural unit, a polymer including an olefin structural unit, a polymer including a urethane structural unit, a polymer including an acrylic structural unit, and/or a combination thereof, for example polydimethylsiloxane, thermoplastic polyurethane (TPU), a styrene-ethylene-butylene-styrene (SEBS), styrene-ethylene-propylene-styrene (SEPS), styrene-butadiene-styrene (SBS), styrene-isoprene-styrene (SIS), styrene-isobutyrene-styrene (SIBS), and/or a combination thereof, but is not limited thereto. The inorganic elastomer-like material may include, for example, but not limited to, a ceramic having elasticity, a solid metal, a liquid metal, and/or a combination thereof. An elastic modulus of the elastomer may be, for example, about 100 Pa to about 109 Pa, but is not limited thereto.

In a plan view, the stretchable region 1000-2 may be surrounded by the non-stretchable region 1000-1 and thus isolated, but is not limited thereto, and/or, the non-stretchable region 1000-1 may be surrounded by the stretchable region 1000-2 and thus isolated.

The non-stretchable region 1000-1 may be a region in which resistance to external force such as twisting, pressing, and pulling is relatively high, so that it is not substantially deformed by the external force or a deformation degree is very small. That is, the non-stretchable region 1000-1 may include a stretch resistance region with very low stretchability due to a large resistance to stretching, in addition to a region with no stretchability at all.

The non-stretchable region 1000-1 may be a region in which the non-stretchable pattern 110b having a high elastic modulus is covered on the stretchable substrate 110a as will be described later, and accordingly it may have substantially the same planar shape as the non-stretchable pattern 110b.

The elastic modulus of the non-stretchable region 1000-1 may be determined by the elastic modulus of the non-stretchable pattern 110b. For example, the elastic modulus of the non-stretchable pattern 110b may be about 100 times or more, within the above range, about 300 times or more, about 500 times or more, or about 1000 times or more, and within the above range, about 100 times to about 108 times, about 500 times to about 108 times, about 1000 times to about 108 times, about 10 times to about 107 times, about 50 times to about 107 times, about 100 times to about 107 times, about 500 times to about 107 times, or about 103 times to about 107 times, higher than that of the stretchable substrate 110a. For example, the elastic modulus of the non-stretchable pattern 110b may be about 104 Pa to about 1012 Pa, but is not limited thereto. Due to the high elastic modulus of the non-stretchable pattern 110b, the non-stretchable region 1000-1 may not be substantially stretched or deformed even if the stretchable substrate 110a is stretched in a predetermined direction.

The non-stretchable pattern 110b may include an organic material, an inorganic material, an organic-inorganic material, and/or a combination thereof with a relatively high elastic modulus, for example polycarbonate, polymethylmethacrylate, polyethyleneterephthalate, polyethylenenaphthalate, polyimide, polyamide, polyamideimide, polyethersulfone, and/or a combination thereof, but is not limited thereto.

The non-stretchable pattern 110b may be formed by, for example, coating or depositing a material (e.g., an organic material) with a relatively high elastic modulus on the stretchable substrate 110a and partially removing it by, for example, etching, to leave the non-stretchable pattern 110b only in the portion corresponding to the non-stretchable region 1000-1. However, the present disclosure is not limited thereto, and the non-stretchable region 1000-1 and the stretchable region 1000-2 having different elastic moduli may be implemented by forming the non-stretchable pattern 110b on the stretchable substrate 110a in various ways.

The non-stretchable pattern 110b includes a plurality of planar patterns 110b-1 and a plurality of bridge patterns 110b-2. A plurality of planar patterns 110b-1 may be repeatedly disposed on the stretchable substrate 110a to define a plurality of planar regions 1000-1A of the non-stretchable region 1000-1, and a plurality of bridge patterns 110b-2 may be repeatedly disposed on the stretchable substrate 110a to define a plurality of bridge regions 1000-1B of the non-stretchable region 1000-1.

The plurality of planar regions 1000-1A may be regions occupied by a plurality of pixels PX of the stretchable panel 1000, and the plurality of pixels PX may be repeatedly arranged along rows and/or columns. Each pixel PX may include a plurality of subpixels, and the plurality of subpixels included in each pixel PX may have an arrangement such as 3×1, 2×2, 3×3, or 4×4, but is not limited thereto. The arrangement of the plurality of pixels PXs (or subpixels) may be the same as that of the unit element 130 to be described later, and may be, for example, a Bayer matrix, a Pentile matrix, and/or a diamond matrix. matrix), but is not limited thereto. In the following description, a pixel and a subpixel may be used interchangeably.

The planar pattern 110b-1 defining each planar region 1000-1A may have a predetermined area, and a unit element 130, which will be described later, and at least a portion of a pixel circuit (not shown) that drives the unit element 130 may be disposed thereon. Since each unit element 130 is disposed on each planar pattern 110b-1, the size (area) of each planar pattern 110b-1 may be larger than the size (area) of each unit element 130.

The plurality of bridge regions 1000-1B may be defined by bridge patterns 110b-2, and each bridge pattern 110b-2 may connect adjacent planar patterns 110b-1. The bridge pattern 110b-2 may have, for example, a linear shape. A wire electrode 500, which will be described later, may be mainly disposed on the bridge pattern 110b-2. Because the wire electrode 500 is disposed in each bridge pattern 110b-2, a width of each bridge pattern 110b-2 may be equal to or wider than a width of each wire electrode 500.

Although the arrangement of the planar region 1000-1A and the bridge region 1000-1B may be variously modified according to the arrangement of the plurality of unit elements 130 and the wire electrode 500, the planar region 1000-1A and the bridge region 1000-1B may be arranged in a geometric pattern when the stretchable substrate 110a is stretched, so that a three-dimensional deformation may occur. The geometric pattern may include, for example, a kirigami pattern including incision lines, but is not limited thereto. The geometric pattern of the non-stretchable region 1000-1 is such that when an external force such as twisting, pressing, or pulling in a predetermined direction is applied to the stretchable panel 1000, even if the non-stretchable region 1000-1 is not flexibly stretched by an external force unlike the stretchable substrate 110a, three-dimensional deformation of the stretchable panel 1000 may be enabled.

Each unit element 130 included in each planar region 1000-1A of the non-stretchable region 1000-1 may be, for example, a light emitting diode such as an organic light emitting diode, an inorganic light emitting diode, a quantum dot light emitting diode, a micro light emitting diode, or a perovskite light emitting diode, or a photoelectric conversion diode such as an organic photoelectric conversion diode, an inorganic photoelectric conversion diode, or an organic/inorganic photoelectric conversion diode, and may be the same or different from each other.

As an example, each unit element 130 may be a light emitting diode configured to independently display red, green, blue, and/or a combination thereof.

As an example, each unit element 130 may be a photoelectric conversion diode configured to selectively absorb light of red, green, blue, infrared, or a combination and convert the absorbed light into an electrical signal.

As an example, a portion of the unit element 130 may be a light emitting diode and a portion of the unit element 130 may be a photoelectric conversion diode. The unit elements 130 may also be referred to as electro-optic elements.

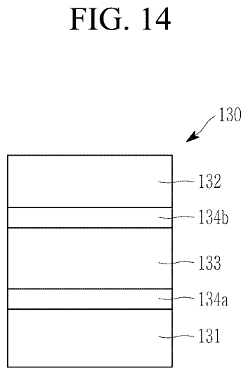

FIG. 14 is a cross-sectional view showing an example of a unit element.

Referring to FIG. 14, the unit element 130 may be a light emitting diode and/or a photoelectric conversion diode and may include an anode 131; a cathode 132; an active layer 133 between the anode 131 and the cathode 132, and optionally auxiliary layers 134a and 134b between the anode 131 and the active layer 133 and/or between the cathode 132 and the active layer 133.

At least one of the anode 131 or the cathode 132 may be a light transmitting electrode. In other words, least one of the anode 131 or the cathode 132 may be transparent to a wavelength of light produced by the unit element 130. For example, the anode 131 may be a light transmitting electrode and the cathode 132 may be a reflective electrode. For example, the anode 131 may be a reflective electrode and the cathode 132 may be a light transmitting electrode. For example, the anode 131 and the cathode 132 may each be a light transmitting electrode. At least one of the anode 131 and the cathode 132 may be a stretchable electrode. the stretchable electrode may include, for example, a stretchable conductor or may have a stretchable shape such as a wavy shape, a pleat shape, a pop-up shape, or a non-planar mesh shape. The stretchable electrode may have, for example, a plurality of microcracks, and since the plurality of microcracks are separated from each other like small holes, flexibility may be provided to the stretchable electrode by extending along the stretching direction during stretching while maintaining the electrical movement path in the stretchable electrode.

The active layer 133 may be a light emitting layer or a photoelectric conversion layer.

The light emitting layer may be configured to emit light in a red wavelength region, a green wavelength region, a blue wavelength region, an infrared wavelength region, an ultraviolet wavelength region, and/or a combination thereof, and may include, for example, an organic light emitting layer, an inorganic light emitting layer (including a quantum dot light emitting layer), an organic/inorganic light emitting layer, and/or a combination thereof. The light emitting layer may include at least one host material and at least one dopant.

The photoelectric conversion layer may be configured to absorb light in a red wavelength region, a green wavelength region, a blue wavelength region, an infrared wavelength region, an ultraviolet wavelength region, and/or a combination thereof, and may be configured to convert the absorbed light into an electrical signal, and may be an organic photoelectric conversion layer, an inorganic photoelectric conversion layer, an organic/inorganic photoelectric conversion layer, and/or a combination thereof. The photoelectric conversion layer may include a p-type semiconductor and an n-type semiconductor, and the p-type semiconductor and the n-type semiconductor may form a pn junction.

The auxiliary layers 134a and 134b may be, for example, charge auxiliary layers, and may be, for example, a hole transport layer, a hole injection layer, an electron blocking layer, an electron transport layer, an electron injection layer, a hole blocking layer, and/or a combination thereof, but are not limited thereto.

Each unit element 130 may be independently controlled and/or driven by a pixel circuit (not shown), and the pixel circuit may include a plurality of thin film transistors (TFT) and a capacitor.

Referring again to FIG. 2, the wire electrode 500 may be on the plurality of bridge patterns 110b-2 and the plurality of planar patterns 110b-1, and may electrically connect the plurality of unit elements 130 or connect the unit element 130 and a pixel circuit in the pixel PX. The wire electrode 500 may include, for example, a gate wire including a gate electrode, a data wire including a source electrode, and/or a driving voltage wire, but is not limited thereto.

Hereinafter, various examples of the wire electrode 500 will be described with reference to FIGS. 3 to 11.

Referring to FIG. 3, the wire electrode 500 according to one example is formed on a stretchable substrate 110a covered with a non-stretchable pattern 110b. That is, the wire electrode 500 is disposed in the aforementioned non-stretchable region 1000-1. The non-stretchable pattern 110b may be the aforementioned planar pattern 110b-1 and/or the bridge pattern 110b-2.

The wire electrode 500 according to one example includes a rigid electrode 510 and a soft electrode 520.

The rigid electrode 510 may include a first conductive layer 511 including a conductor with relatively high electrical conductivity (hereinafter referred to as “first conductor”), and may not have stretchability or may have very low stretchability due to the general characteristics of the first conductor, which has relatively high electrical conductivity. The first conductor may include a conductor including, for example, a metal, a conductive nanomaterial, a two-dimensional conductor, a conductive oxide, and/or a combination thereof, but is not limited to. The first conductor may be, for example, a metal or a metal alloy, for example, silver (Ag), gold (Au), copper (Cu), aluminum (Al), nickel (Ni), molybdenum (Mo), an alloy thereof, and/or a combination thereof, but is not limited to thereto. A thickness of the first conductive layer 511 (e.g., in the Z direction) may be about 5 nm to about 500 nm, and within the above range, about 10 nm to about 400 nm or about 10 nm to about 300 nm.

The soft electrode 520 includes a second conductive layer 522 and an elastic layer 521 under the second conductive layer 522.

The second conductive layer 522 may be in close contact with the upper surface of the elastic layer 521, and may have a number of microcracks that are intentionally and/or unintentionally generated as the elastic layer 521 is stretched. Since the plurality of microcracks are separated from each other, the second conductive layer 522 may maintain an electrical connection path within the second conductive layer 522 and expand along the stretching direction during stretching to provide flexibility to the soft electrode 520.

The second conductive layer 522 may include a second conductor that is the same as or different from the first conductor, and the second conductor may be, for example, a metal or a metal alloy. The second conductor may be, for example, silver (Ag), gold (Au), copper (Cu), aluminum (Al), nickel (Ni), molybdenum (Mo), an alloy thereof, and/or a combination thereof, but is limited thereto. A thickness of the second conductive layer 522 may be about 2 nm to about 200 nm, about 5 nm to about 200 nm, and/or about 5 nm to about 100 nm.

The elastic layer 521 may be under the second conductive layer 522 and thus may be configured to effectively absorb the strain applied on the second conductive layer 522 when the stretchable panel 1000 is stretched in a predetermined direction and may provide the wire electrode 500 with a certain degree of flexibility and/or stretchability.

The elastic layer 521 may include an elastomer and a second conductor.

The elastomer may be an elastic material with a relatively low glass transition temperature (e.g., less than about 80° C.), such as polyorganosiloxane, a polymer including a butadiene structural unit, a polymer including an olefin structural unit, a polymer including a urethane structural unit, a polymer including an acrylic structural unit, and/or a combination thereof, but is not limited thereto. The elastomer may include for example polydimethylsiloxane, thermoplastic polyurethane (TPU), styrene-ethylene-butylene-styrene (SEBS), styrene-ethylene-propylene-styrene (SEPS), styrene-butadiene-styrene (SBS), styrene-isoprene-styrene (SIS), styrene-isobutyrene-styrene (SIBS), and/or a combination thereof, but is not limited thereto.

The second conductor may be a conductive material diffused and/or penetrated from the second conductive layer 522 into the elastic layer 521 during the formation step and/or subsequent steps of the second conductive layer 522. Specifically, particles (e.g., metal particles) of the second conductor included in the second conductive layer 522 may be transferred from the interface between the second conductive layer 522 and the elastic layer 521 to the inside (e.g., free volume between elastic polymers) of the elastic layer 521 and the particles of the second conductor or clusters of these particles (e.g., metal clusters) may have spread in the depth direction of the elastic layer 521. Accordingly, the second conductor included in the elastic layer 521 may exist in a form of, for example, metal particles and/or metal clusters.

Since the second conductor included in the elastic layer 521 is diffused from the second conductive layer 522, the distribution of the second conductor along the thickness direction of the elastic layer 521 may be uneven and/or not uniform, and for example, it may be mainly distributed in a region closer to the elastic layer 521.

For example, when the elastic layer 521 has a first region (upper region) relatively close to the second conductive layer 522 along a thickness direction of the elastic layer 521 and a second region (lower region) relatively far from the second conductive layer 522, the first region (upper region) of the elastic layer 521 may include a second conductor in a larger content than in the second region (lower region) of the elastic layer 521. Herein, the first region (upper region) and the second region (lower region) of the elastic layer 521 are defined by arbitrarily dividing a total thickness of the elastic layer 521 into two halves according to their relative positions from the second conductive layer 522 and for example, may have a thickness ratio of about 5:5, but is not limited thereto. Herein, the elastic layer 521, for example, may have a thickness of about 3 nm to 50 nm and within the range, about 5 nm to about 40 nm, about 5 nm to about 30 nm, or about 5 nm to about 20 nm.

For example, the content of the second conductor included in the elastic layer 521 may be gradually changed according to a thickness direction (e.g., Z direction) of the elastic layer 521, for example, the second conductor included in the elastic layer 521 may be most present on the first surface 521q of the elastic layer 521 contacting with the second conductive layer 522 but least present on the second surface 521p of the elastic layer 521 (e.g., the surface of the elastic layer 521 contacting with the first conductive layer 511), and in the middle, the content of the second conductor may gradually decrease from the first surface 521q of the elastic layer 521 to the second surface 521p.

Since the elastic layer 521 may include a second conductor (e.g., metal) diffused and/or penetrated from the second conductive layer 522 the elastic layer 521 may provide an electrical connection path between the first conductive layer 511 and the second conductive layer 522 to electrically connect the first conductive layer 511 and the second conductive layer 522.

A forming the soft electrode 520 may include, for example, forming the second conductive layer 522 at the same or higher temperature than a glass transition temperature of an elastomer of the elastic layer 521, which may be performed, for example, by thermal deposition (for example, vacuum thermal deposition). For example, the forming of the soft electrode 520 may include preparing a thermal evaporator in which the elastic layer 521 and a boat or crucible containing a metal sample face each other in a vacuum chamber or evaporating the metal sample by heating the boat or crucible to thermally deposit the metal on the surface of the elastic layer 521. The heat applied to the boat or crucible may be, for example, resistive heat.

For example, in the step of heating the boat or crucible, radiant heat generated by the heat may increase a temperature inside the vacuum chamber, wherein the temperature inside the vacuum chamber may be, for example, the same as or higher than the glass transition temperature of an elastomer of the elastic layer 521. In addition, in the heating the boat or crucible, the radiant heat generated by the heat may also increase a surface temperature of the elastic layer 521, wherein the surface temperature of the elastic layer 521 may be, for example, the same as or higher than the glass transition temperature of an elastomer. In this way, as the temperature of the vacuum chamber and/or the surface temperature of the elastic layer 521 increases, flexibility and free space of polymer chains of the elastomer of the elastic layer 521 also increase, resulting in increasing penetration and/or diffusion of the second conductor (e.g., metal) from the second conductive layer 522 into the elastic layer 521.

An amount of the second conductor (e.g., metal) penetrated and/or diffused into the elastic layer 521 may be, for example, adjusted by a deposition rate, for example, if deposited at a slow deposition rate for a long term, metal atoms are diffused into a relatively deep depth (thickness), but for example, if deposited at a fast deposition rate, the metal atoms may be diffused into a relatively shallow depth (thickness).

For example, the metal deposition rate may be, for example, greater than or equal to about 0.001 angstrom per second (A/s), greater than or equal to about 0.002 Å/s, greater than or equal to about 0.005 Å/s, greater than or equal to about 0.007 Å/s, greater than or equal to about 0.01 Å/s, greater than or equal to about 0.002 Å/s, greater than or equal to about 0.005 Å/s, and/or greater than or equal to about 0.007 Å/s, for example, less than or equal to about 20 Å/s, less than or equal to about 15 Å/s, and/or less than or equal to about 10 Å/s. For example, less than or equal to about 5 Å/s, less than or equal to about 3 Å/s, less than or equal to about 2 Å/s, less than or equal to about 1 Å/s, less than or equal to about 0.5 Å/s, less than or equal to about 0.4 Å/s, less than or equal to about 0.3 Å/s, less than or equal to about 0.2 Å/s, or less than or equal to about 0.1 Å/s, and within the ranges, about 0.001 Å/s to 20 Å/s, about 0.001 Å/s to 15 Å/s, about 0.001 Å/s to 10 Å/s, about 0.001 Å/s to 5 Å/s, about 0.001 Å/s to 3 Å/s, about 0.001 Å/s to 2 Å/s, about 0.001 Å/s to 1 Å/s, about 0.001 Å/s to 0.5 Å/s, about 0.001 Å/s to 0.4 Å/s, about 0.001 Å/s to 0.3 Å/s, about 0.001 Å/s to 0.2 Å/s, or about 0.001 Å/s to 0.1 Å/s.

The soft electrode 520 includes the elastic layer 521 and the second conductive layer 522, wherein the elastic layer 521 includes a second conductor (e.g., metal) diffused and/or penetrated from the second conductive layer 522 and is electrically connected to the second conductive layer 522 as well as thus has flexibility and/or stretchability due to the elastic layer 521 itself.

In this way, since the wire electrode 500 has the rigid electrode 510 with no stretchability but high electrical conductivity and the soft electrode 520 with stretchability, wherein the rigid electrode 510 and the soft electrode 520 are connected each other, when the stretchable panel 1000 is deformed by an external force, even though the rigid electrode 510 is damaged, for example, cracked and the like by an external force applied to the wire electrode 500, a current is transferred from the rigid electrode 510 to the soft electrode 520 to prevent a short circuit of the wire electrode 500.

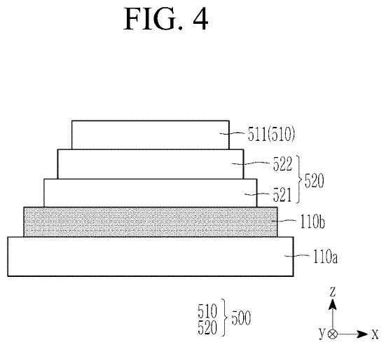

Referring to FIG. 4, the wire electrode 500 according to some embodiments, like in the aforementioned embodiments, includes the rigid electrode 510 and the soft electrode 520 on a region of the stretchable substrate 110a, which is covered with the non-stretchable pattern 110b, wherein the rigid electrode 510 includes the first conductive layer 511, and the soft electrode 520 includes the elastic layer 521 and the second conductive layer 522.

However, in the wire electrode 500 according to the present embodiments, unlike in the aforementioned embodiment, the soft electrode 520 is under the rigid electrode 510. In other words, the wire electrode 500 includes the elastic layer 521, the second conductive layer 522, and the first conductive layer 511 stacked in order from the stretchable substrate 110a, which is covered with the non-stretchable pattern 110b. The first conductive layer 511, the elastic layer 521, and the second conductive layer 522 are otherwise the same as (and/or substantially similar to) the first conductive layer 511, the elastic layer 521, and the second conductive layer 522 described above.

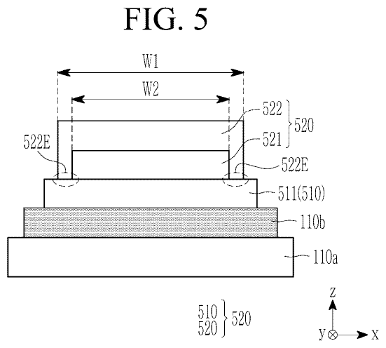

Referring to FIG. 5, the wire electrode 500 according to some embodiments, like in the aforementioned embodiments, includes the rigid electrode 510 and the soft electrode 520 formed on the stretchable substrate 110a on the region of the stretchable substrate 110a, which is covered with the non-stretchable pattern 110b, wherein the rigid electrode 510 includes the first conductive layer 511, and the soft electrode 520 includes the elastic layer 521 and the second conductive layer 522.

However, in the wire electrode 500 according to the present embodiments, the second conductive layer 522 has a wider width W1 than a width W2 of the elastic layer 521. Accordingly, since a portion (e.g., an edge portion 522E) of the second conductive layer 522 may be in contact with the first conductive layer 511, the wire electrode 500 may not only have stretchability but also further effectively improve electrical characteristics due to direct electrical connection between the first conductive layer 511 and the second conductive layer 522. The first conductive layer 511, the elastic layer 521, and the second conductive layer 522 are otherwise the same and/or substantially similar to the first conductive layer 511, the elastic layer 521, and the second conductive layer 522 as described above.

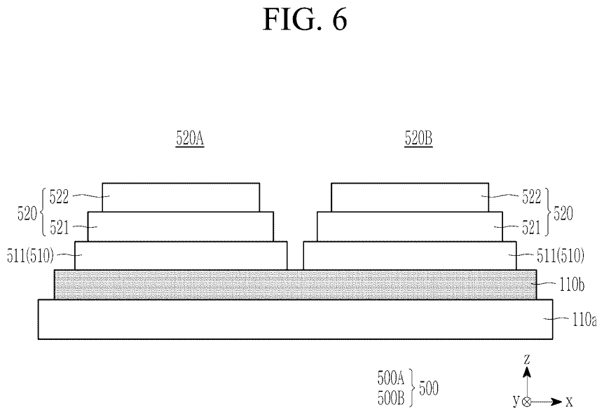

Referring to FIG. 6, the wire electrode 500 according to some embodiments, like in the aforementioned embodiments, includes the rigid electrode 510 and the soft electrode 520 on the region of the stretchable substrate 110a, which is covered with the non-stretchable pattern 110b, wherein the rigid electrode 510 includes the first conductive layer 511, and the soft electrode 520 includes the elastic layer 521 and the second conductive layer 522.

However, in the present embodiments, two wire electrodes 500A and 500B are in parallel on the non-stretchable pattern 110b. For example, the wire electrodes 500A and 500B may be the same or different from each other, for example, independently a gate wire, a data wire, and/or a driving voltage wire. The first conductive layers 511, the elastic layers 521, and the second conductive layers 522 of the wire electrodes 500A and 500B are the same as described above.

FIG. 6 shows a stacking structure of the wire electrode 500 shown in FIG. 3, that is, a structure of stacking the first conductive layer 511, the elastic layer 521, and the second conductive layer 522 in order from the stretchable substrate 110a covered with the non-stretchable pattern 110b but is not limited thereto, and the wire electrodes 500A and 500B of the embodiments may be equally applied to a structure of stacking the elastic layer 521, the second conductive layer 522, and the first conductive layer 511 in order from the stretchable substrate 110a on the stretchable substrate 110a covered with the non-stretchable pattern 110b, which is shown in FIG. 4, and/or a structure of contacting the portion (e.g., edge portion 522E) of the second conductive layer 522 with the first conductive layer 511 due to a wider width W1 of the second conductive layer 522 than a width W2 of the elastic layer 521, which is shown in FIG. 5.

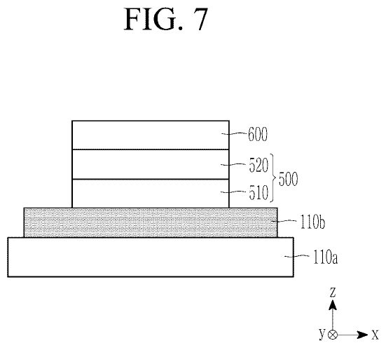

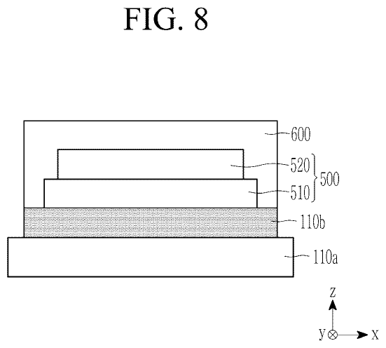

Referring to FIGS. 7 and 8, the wire electrode 500 according to some embodiments, like in the aforementioned embodiments, includes the rigid electrode 510 and the soft electrode 520 formed on the stretchable substrate 110a which is covered with the non-stretchable pattern 110b. The rigid electrode 510 and the soft electrode 520 are the same as and/or substantially similar to the rigid electrode 510 and the soft electrode 520 described above.

However, in the embodiments, a protective layer 600 is further included on the wire electrode 500. The protective layer 600, as shown in FIG. 7, may be formed on top of the wire electrode 500, but as shown in FIG. 8, may cover the top and side portions of the wire electrode 500. The protective layer 600 may include for example a non-stretchable layer, and may include for example polycarbonate, polymethylmethacrylate, polyethyleneterephthalate, polyethylenenaphthalate, polyimide, polyamide, polyamideimide, polyethersulfone, and/or a combination thereof. When the stretchable panel 1000 is deformed by an external force, the protective layer 600 may reduce strain applied to the wire electrode 500, and thus effectively decrease a strain rate of the wire electrode 500.

FIGS. 7 and 8 show a stacking structure of the wire electrode 500 shown in FIG. 3, that is, a structure of stacking the rigid electrode 510 and the soft electrode 520 in order from the stretchable substrate 110a covered with the non-stretchable pattern 110b but is not limited thereto, the protective layer 600 may be equally applied to the structure shown in FIG. 4 in which the first conductive layer 511, the second conductive layer 522, and the elastic layer 521 in order are stacked from the stretchable substrate 110a covered with the non-stretchable pattern 110b or the structure shown in FIG. 5, in which the portion (e.g., edge portion 522E) of the second conductive layer 522 is in contact with the first conductive layer 511 due to the wider width W1 of the second conductive layer 522 than the width W2 of the elastic layer 521.

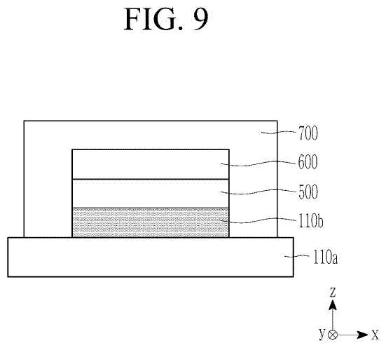

Referring to FIGS. 9 to 11, the wire electrode 500 according to some embodiments, like in the aforementioned embodiments, includes the wire electrodes 500, 500A, and 500B and the protective layer 600 on the stretchable substrate 110a covered with the non-stretchable pattern 110b. The wire electrodes 500, 500A, and 500B and the protective layer 600 are otherwise the same as and/or substantially similar to the wire electrodes 500, 500A, and 500B and the protective layer 600 described above.

However, in the present embodiments, an additional protective layer 700 covering the wire electrodes 500, 500A, and 500B and the protective layer 600 is further included. This protective layer 700 may be a soft protective layer including an elastomer, when the stretchable panel 1000 is deformed by an external force, it may reduce strain applied to the wire electrodes 500, 500A, and 500B and further effectively protect the wire electrodes 500, 500A, and 500B.

Hereinafter, another example of a stretchable panel according to some example embodiments will be described.

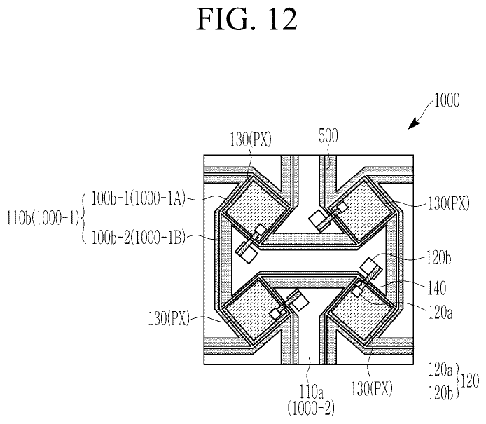

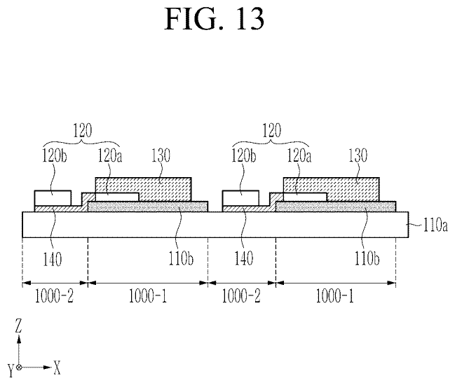

FIG. 12 is a plan view of a stretchable panel according to some embodiments, showing an enlarged portion of “A” in FIG. 1, and FIG. 13 is a cross-sectional view of an example of the stretchable panel of FIG. 12.

Referring to FIG. 12, the stretchable panel 1000 according to some embodiments, as described in the aforementioned embodiments, includes the stretchable region 1000-2 and the non-stretchable region 1000-1, wherein the stretchable region 1000-2 may be a region not covered with the non-stretchable pattern 110b on the stretchable substrate 110a, and the non-stretchable region 1000-1 may be a region covered with the non-stretchable pattern 110b. The non-stretchable pattern 110b may include a plurality of planar patterns 110b-1 and a plurality of bridge patterns 110b-2, wherein a plurality of unit elements 130 defining a plurality of pixels PX are on the plurality of planar patterns 110b-1, and the wire electrode 500 may be in the plurality of planar patterns 110b-1 and a plurality of bridge regions 1000-1B. The stretchable substrate 110a, the non-stretchable pattern 110b, the planar patterns 110b-1, the bridge patterns 110b-2, the unit elements 130, and the wire electrode 500 are the same as described above.

However, the stretchable panel 1000 according to the present embodiments, unlike the stretchable panel 1000 according to the aforementioned embodiments, includes a pixel circuit 120 electrically connected to each unit element 130, wherein the pixel circuit 120 includes a first pixel circuit 120a and a second pixel circuit 120b separated each other and further includes a connection electrode 140 connecting the first pixel circuit 120a and the second pixel circuit 120b. At least a portion of the first pixel circuit 120a or the second pixel circuit 120b may be in the stretchable region 1000-2.

The pixel circuit 120 may be repeatedly arranged on the stretchable substrate 110a and may be arranged around each pixel PX to independently control and/or drive each pixel PX. The pixel circuit 120 may include elements configured to independently control and/or drive each pixel (or subpixel), and may include, for example, a plurality of thin film transistors (TFTs) and capacitors.

The plurality of TFTs may be electrically connected to one or more wire electrodes, and the wire electrodes 500 may include a gate line transmitting a gate signal (or a scan signal), a data line transmitting a data signal, and/or a driving voltage line transmitting a driving voltage. The TFTs may include at least switching thin film transistor (switching TFT) and at least one driving thin film transistor (driving TFT).

Each pixel circuit 120 includes a first pixel circuit 120a and a second pixel circuit 120b that are disposed in or near one pixel PX and separated from each other but are electrically connected to each other. At least a portion of the first pixel circuit 120a or the second pixel circuit 120b may be in the stretchable region 1000-2.

For example, the first pixel circuit 120a may be in the non-stretchable region 1000-1 that is formed on the non-stretchable pattern 110b and the second pixel circuit 120b may be formed on the stretchable substrate 110a on which the non-stretchable pattern 110b is not formed and may be disposed in the stretchable region 1000-2. For example, the first pixel circuit 120a may include a non-stretchable thin film transistor (non-stretchable TFT) and a capacitor, and the second pixel circuit 120b may include a stretchable thin film transistor (stretchable TFT).

The non-stretchable TFT may include a non-stretchable semiconductor layer as an active layer. The non-stretchable semiconductor layer may include an inorganic semiconductor layer and may include, for example, silicon, an oxide semiconductor, and/or a combination thereof.

The stretchable TFT may include a stretchable semiconductor layer as an active layer. The stretchable semiconductor layer may include, for example, an organic semiconductor, two-dimensional material, or a combination. The organic semiconductor may include, for example, a low molecular semiconductor, a polymer semiconductor, and/or a combination thereof. The two-dimensional material may include at least one metal element such as Mo, W, Nb, Ta, Pt, Pd, Co, Cr, Cu or Ni and at least one of chalcogen element such as S, Se or Te. For example, the two-dimensional material may include MoS₂, MoSe₂, MoSSe, MoSTe, Mo₍₁₋ₓ₎WₓS₂, Mo₍₁₋ₓ₎WₓSe₂, Mo₍₁₋ₓ₎WₓTe₂, Mo₍₁₋ₓ₎NbₓS₂, Mo₍₁₋ₓ₎NbₓSe₂, Mo₍₁₋ₓ₎TaₓS₂, Mo₍₁₋ₓ₎TaₓSe₂, Mo₍₁₋ₓ₎WₓSSe, MoTe₂, WS₂, WSe₂, WSSe, WTe₂, WSTe, W₍₁₋ₓ₎NbₓS₂, W₍₁₋ₓ₎NbₓSe₂, PtS₂, PtSe₂, PtTe₂, PdSe₂, TaS₂, TaSe₂, Ta₍₁₋ₓ₎WₓS₂, Ta₍₁₋ₓ₎WₓSe₂ (herein, 0≤x≤1), and/or a combination thereof.

The stretchable semiconductor layer may include, for example, a semiconductor material and an elastomer. The semiconductor material may include, for example, an organic semiconductor, an oxide semiconductor, two-dimensional material, and/or a combination thereof, and the elastomer may include, for example, polydimethylsiloxane (PDMS), styrene-ethylene-butylene-styrene (SEBS), styrene-ethylene-propylene-styrene (SEPS), styrene-butadiene-styrene (SBS), styrene-isoprene-styrene (SIS), styrene-isobutylene-styrene (SIBS), and/or a combination thereof.

For example, one of the non-stretchable TFT and the stretchable TFT may be a switching TFT and the other may be a driving TFT. The switching TFT is electrically connected to the gate line and the data line and may control on/off of the pixel PX, and the driving TFT is electrically connected to the switching TFT and the driving voltage line to drive the pixel PX. For example, the switching TFT may include a first gate electrode electrically connected to a gate line; a first source electrode electrically connected to the data line; a first drain electrode facing the first source electrode; and a first semiconductor layer electrically connected to the first source electrode and the first drain electrode, respectively. For example, the driving TFT may include a second gate electrode electrically connected to the first drain electrode; a second source electrode connected to the driving voltage line; a second drain electrode facing the second source electrode; a second semiconductor layer electrically connected to the second source electrode and the second drain electrode, respectively. The switching TFT and the driving TFT may include the same or different semiconductor layers.

For example, the driving TFT may have relatively high charge transfer characteristics, and may include, for example, silicon, an oxide semiconductor, and/or a combination thereof as an active layer having such high charge transfer characteristics. Since the silicon and/or oxide semiconductor may be a non-stretchable semiconductor layer as described above, the driving TFT may be a non-stretchable TFT.

For example, the switching TFT may have relatively low leakage current characteristic for high on/off characteristics, and may include an organic semiconductor, an oxide semiconductor, two-dimensional material, and/or a combination thereof having such a low leakage current characteristic as an active layer. Since the organic semiconductor, the oxide semiconductor and/or the two-dimensional material may be stretchable semiconductor layers as described above, the switching TFT may be a stretchable TFT.

As described above, a portion of the plurality of TFTs included in each pixel circuit 120 is in a region (stretchable region) other than the pixel PX, so that an area occupied by the TFTs in the pixel PX may be reduced compared with a structure in which all the TFTs are disposed in each pixel PX, thereby overcoming a limitation of the reduction in a size of the pixel PX to effectively decrease the pixel size.

Specifically, the stretchable panel 1000 according to the present embodiment should secure a separate region (e.g., stretchable region 1000-2) for providing stretchability, and accordingly, an area occupied by the pixel PX relative to the total area of the stretchable substrate 110a may be inevitably reduced compared to a general panel (non-stretchable panel) using a rigid substrate, such as a glass substrate.

Meanwhile, in general, the size of the pixel PX cannot be smaller than the area occupied by the pixel circuit 120. In the present embodiments, the area of the pixel circuit 120 in the pixel PX may be effectively reduced by overcoming this limitation and arranging a portion of the pixel circuit 120 (e.g., a portion of the TFTs) in an area (stretchable area) other than the pixel PX, and accordingly, the size of the pixel PX may also be effectively reduced. Accordingly, the stretchable panel 1000 having a high resolution may be realized by overcoming the limitation of spatial arrangement of the stretchable panel 1000 and increasing the number of pixels PX per unit area on the stretchable substrate 110a.

In FIGS. 12 and 13, the first pixel circuit 120a and the second pixel circuit 120b are illustrated in arbitrary shapes and sizes for convenience of explanation, but the first pixel circuit 120a and the second pixel circuit 120b are illustrated may vary in shape and size. Also, although the first pixel circuit 120a and the second pixel circuit 120b are shown at arbitrary positions in FIGS. 12 and 13 for convenience of explanation, the first pixel circuit 120a may be anywhere in the non-stretchable region 1000-1 of the stretchable substrate 110a, and the second pixel circuit 120b may be anywhere in the stretchable region 1000-2 of the stretchable substrate 110a.

For example, the number of the second pixel circuits 120b (e.g., switching TFTs) included in each pixel circuit 120 may be equal to or less than the number of the first pixel circuits 120a (e.g., driving TFTs and capacitors) included in each pixel circuit 120. For example, the number of the second pixel circuits 120b (e.g., switching TFTs) included in each pixel circuit 120 may be greater than the number of the first pixel circuits 120a (e.g., driving TFTs and capacitors) included in each pixel circuit 120. For example, the number of first pixel circuits 120a (e.g., driving TFTs and capacitors) included in each pixel circuit 120 may be 1 to 10. For example, the number of second pixel circuits 120b (e.g., switching TFTs) included in each pixel circuit 120 may be 1 to 10.

The connection electrode 140 may electrically connect the first pixel circuit 120a in the non-stretchable region 1000-1 and the second pixel circuit 120b in the stretchable region 1000-2. The connection electrode 140 may be over the stretchable region 1000-2 and the non-stretchable region 1000-1. For example, one end of the connection electrode 140 may be in the stretchable region 1000-2 and the other end of the connection electrode 140 may be in the non-stretchable region 1000-1. The connection electrode 140 may be, for example, a stretchable electrode, and the stretchable electrode may include, for example, a conductive polymer, conductive metal particles, liquid metal, cracked metal such as cracked Au, and/or a combination thereof, but is not limited thereto.

As described above, in the stretchable panel 1000 according to the present embodiments, at least a portion of the pixel circuit 120 (e.g., at least a portion of TFTs) may be in the stretchable region 1000-2, so that a limitation of the pixel arrangement space due to the stretchable region 1000-2 may be overcome and the number of pixels per unit area may be increased. For example, the number of pixels per unit area in the stretchable panel 1000 may be greater than or equal to about 150 ppi (pixel per inch), greater than or equal to about 200 ppi, greater than or equal to about 250 ppi, greater than or equal to about 300 ppi, greater than or equal to about 350 ppi, greater than or equal to about 400 ppi, greater than or equal to about 450 ppi, or greater than or equal to about 500 ppi and may be, for example, about 150 ppi to about 1000 ppi, about 200 ppi to about 1000 ppi, about 250 ppi to about 1000 ppi, about 300 ppi to about 1000 ppi, about 350 ppi to about 1000 ppi, about 400 ppi to about 1000 ppi, about 450 ppi to about 1000 ppi, or about 500 ppi to about 1000 ppi.

Hereinafter, another example of a stretchable panel according to some example embodiments will be described.

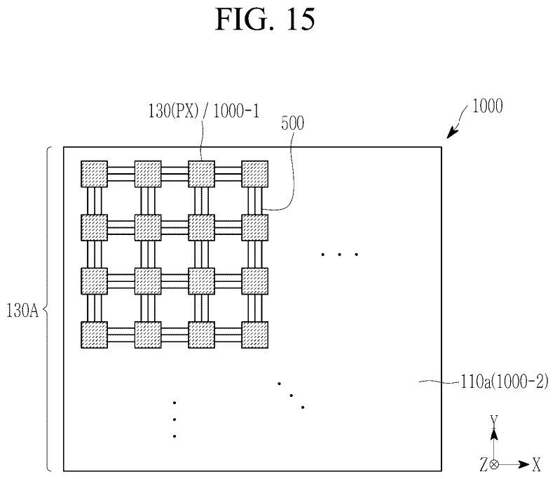

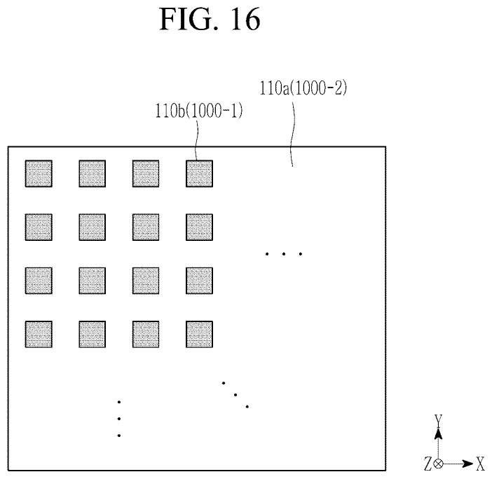

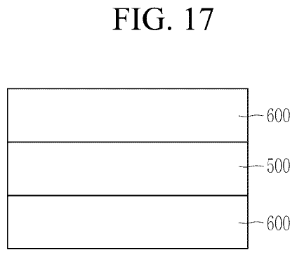

FIG. 15 is a plan view schematically showing an example of a stretchable panel according to some example embodiments, FIG. 16 is a plan view showing an example of the arrangement of the non-stretchable pattern 110b in the stretchable panel of FIG. 15, and FIG. 17 is a cross-sectional view showing an example of a wire electrode in the stretchable panel of FIG. 15.

Referring to FIGS. 15 and 16, the stretchable panel 1000 according to some embodiments, like the aforementioned embodiments, includes the stretchable region 1000-2 and the non-stretchable region 1000-1, wherein the stretchable region 1000-2 may be a region not covered with the non-stretchable pattern 110b on a stretchable substrate 110a, and the non-stretchable region 1000-1 may be a region covered with the non-stretchable pattern 110b.

However, the stretchable panel 1000 according to the present embodiments, unlike the stretchable panel 1000 according to the aforementioned embodiments, includes a plurality of island-shaped patterns 110b-3 where the non-stretchable patterns 110b are separated one another on the stretchable substrate 110a. Each unit element 130 is positioned on each island-shaped pattern 110b-3 (the non-stretchable region 1000-1), and the wire electrode 500 is mainly positioned on the stretchable substrate 110a (the stretchable region 1000-2).

The wire electrode 500 may be mainly in the stretchable region 1000-2 and electrically connect the neighboring unit elements 130 between neighboring island-shaped pattern 110b-3. For example, the wire electrode 500 may include a gate wire extending in a first direction (e.g., X direction) and a data wire and/or a driving voltage wire extending in a second direction (e.g., Y direction) but is not limited thereto.

In the drawing, the wire electrode 500 is illustratively shown as a straight line extending in the first direction (e.g., X direction) and the second direction (e.g., Y direction) but is not limited thereto and may have a stretchable shape such as a wave shape, a pop-up shape, a non-planar mesh shape, and/or the like.

The wire electrode 500, as described above, includes the rigid electrode 510 and the soft electrode 520, wherein the rigid electrode 510 includes the first conductive layer 511, and the soft electrode 520 includes the elastic layer 521 and the second conductive layer 522. The wire electrode 500 is the same as described above.

For example, as shown in FIG. 17, the wire electrode 500 further includes the protective layer 600 under and/or on the wire electrode 500. The protective layer 600 may include for example a non-stretchable layer, and may include for example polycarbonate, polymethylmethacrylate, polyethyleneterephthalate, polyethylenenaphthalate, polyimide, polyamide, polyamideimide, polyethersulfone, and/or a combination thereof. The protective layer 600 may protect the wire electrode 500 under and/or on the wire electrode 500 disposed in the stretchable region 1000-2 and, when the stretchable panel 1000 is deformed by an external force, it may reduce strain applied to the wire electrode 500 to efficiently reduce a strain rate of the wire electrode 500.

The aforementioned stretchable panel 1000 may be applied to various fields requiring flexibility and/or stretchability, and may be, for example, a stretchable display panel or a stretchable sensor array. The stretchable panel 1000 may be, for example, a bendable display panel, a foldable display panel, a rollable display panel, a wearable device, a skin-type stretchable display panel, a skin-like display panel, a skin-like sensor array, a large-area conformable display, smart clothing, or the like, but is not limited thereto.

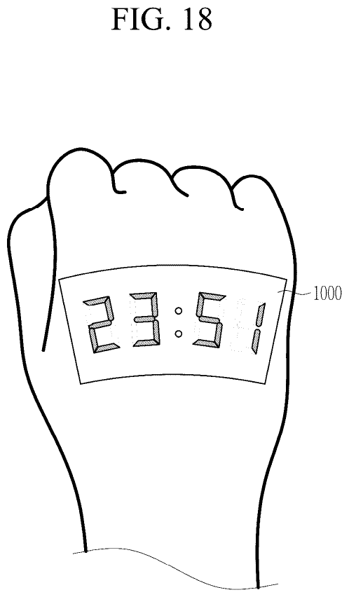

FIG. 18 is a schematic view showing a skin-type stretchable display panel according to an example.

Referring to FIG. 18, the aforementioned stretchable panel 1000 may be a skin-type display panel that is an ultrathin display panel, and may display predetermined information such as various characters and/or images. The stretchable panel 1000 may include, e.g., a skin-safe adhesive and may be connected to a display driver and/or processing circuitry (not shown) configured to drive and/or control the stretchable panel 1000. An example skin-type display panel is described in further detail below.

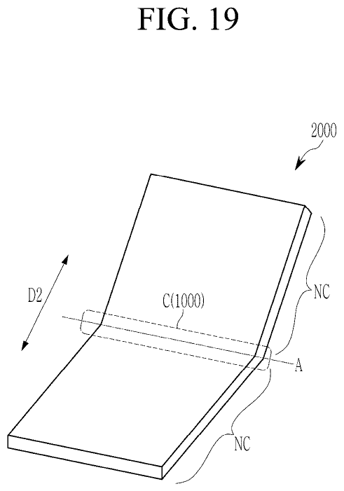

FIGS. 19 to 22 are schematic views each showing examples of a stretchable display panel according to examples.

The stretchable display panel 2000 according to the examples may be a display panel flexibly deformed by a user or an external force by introducing a structurally deformable portion into a screen for displaying an image. Herein, the structurally deformable portion may be at least a portion inside the screen for example, portion corresponding to a hinge or joint in the screen.

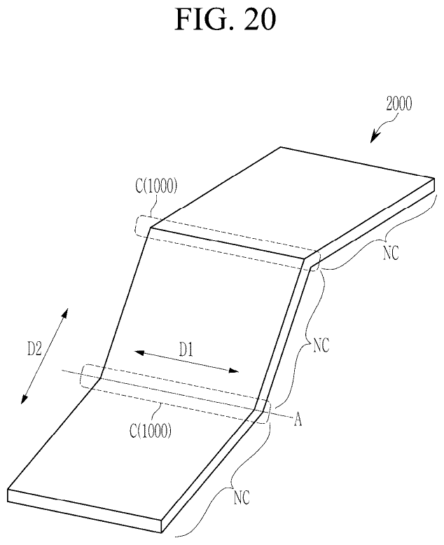

Referring to FIGS. 19 and 20, the stretchable display panel 2000 according to an example may be a foldable display panel of which a screen can be folded into one or more than one along a predetermined direction. The foldable display panel shown in FIG. 19 is a short foldable display panel of which a screen may be folded along one axis (A), and the stretchable display panel 2000 shown in FIG. 20 is a multi-axis foldable display panel of which a screen may be folded along two axes (A). However, the present invention is not limited thereto, and the number of axis (A) may be one, two, three or more. FIG. 19 illustrates an in-folding method in which the screen is folded inward, but the present invention is not limited thereto but may be similarly applied to an out-folding method in which the screen is folded outward.

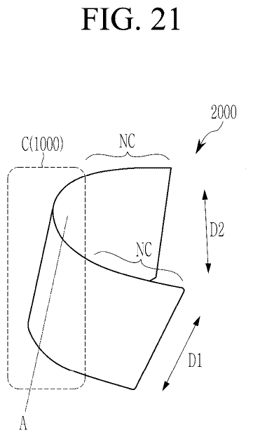

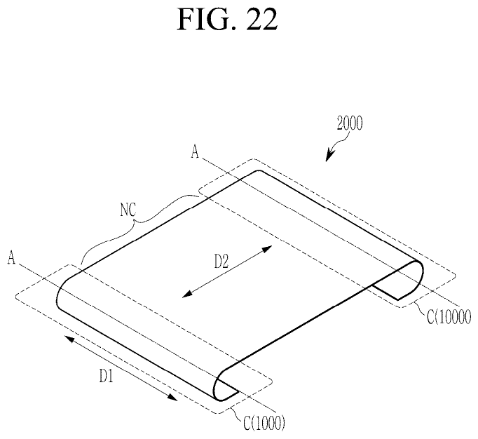

Referring to FIG. 21, the stretchable display panel 2000 according to at least one example may be a bendable display panel capable of bending a screen along a predetermined direction. Referring to FIG. 22, the stretchable display panel 2000 according to at least one example may be a rollable display panel configured to roll the screen along at least one direction.

Referring to FIGS. 19 to 22, the stretchable display panel 2000 may be folded, bent, or rolled along at least one axis A extending the first direction D1. The stretchable display panel 2000 may include a deformable section C folded, bent, or rolled along the axis A and a non-deformable section NC excluding the deformable section C.

The deformable section C may be a folding section, a bending section, or a rolling section which is deformed into a curve around the axis A, wherein one or more than one may be included in the stretchable display panel 2000. The deformable section C may be a region where a radius of curvature, which refers to a degree of being folded, bent, or rolled up to a maximum without substantial damage, is defined and where stress is concentrated, when repetitively folded, bent, or rolled. The stress may act on the deformable section C in a direction of being repetitively folded, bent, or rolled, for example, in a second direction D2 substantially perpendicular to the first direction D1. The non-deformable section NC may be a flat section or have relatively smaller stress than the deformable section C, but the present disclosure is not limited thereto.

The deformable section C of the stretchable display panel 2000 may include the stretchable panel 1000 including the non-stretchable region 1000-1 and the stretchable region 1000-2 shown in FIGS. 1 to 17.

The stretchable region 1000-2 is a region capable of flexibly responding to an external force such as twisting, pressing, and pulling and may include, as described above, an elastomer having a relatively low elastic modulus, and accordingly, may provide the deformable section C of the stretchable display panel 2000 with stretchability to reduce stress acting when repetitively folded, bent, or rolled and thus prevent or reduce damage in the deformable section C.

The non-stretchable region 1000-1 is a region that is not substantially deformed or very slightly deformed due to relatively high resistance to the external force such as twisting, pressing, and pulling and may include an organic material, an inorganic material, an organic/inorganic material, and/or a combination thereof, which has a relatively high elastic modulus, as described above.

The wire electrode 500, as shown in FIGS. 3 to 11 or FIG. 17, includes the rigid electrode 510 and the soft electrode 520, which are electrically connected each other and, when a deforming section C of the stretchable display panel 2000 is deformed by an external force, even though the rigid electrode 510 is damaged, for example, cracked and the like by strain applied to the wire electrode 500, a current may be transferred from the rigid electrode 510 to the soft electrode 520 to prevent a short circuit of the wire electrode 500.

As an example, in the deformable section C of the stretchable display panel 2000, at least a portion of the pixel circuit 120 (e.g., at least a portion of a thin film transistor) may be disposed in the stretchable region 1000-2, as shown in FIGS. 12 and 13 described above so that a limitation of the pixel arrangement space due to the stretchable region 1000-2 may be overcome and the number of pixels per unit area may be increased. For example, in the deformable section C, the number of pixels per unit area may be greater than or equal to about 150 ppi (pixel per inch), greater than or equal to about 200 ppi, greater than or equal to about 250 ppi, greater than or equal to about 300 ppi, greater than or equal to about 350 ppi, greater than or equal to about 400 ppi, greater than or equal to about 450 ppi, or greater than or equal to about 500 ppi, for example, about 150 ppi to about 1000 ppi, about 200 ppi to about 1000 ppi, about 250 ppi to about 1000 ppi, about 300 ppi to about 1000 ppi, about 350 ppi to about 1000 ppi, about 400 ppi to about 1000 ppi, about 450 ppi to about 1000 ppi, or about 500 ppi to about 1000 ppi. Accordingly, the deformable section C of the stretchable display panel 2000 may realize substantially the same resolution in the non-deformable section NC, and resultantly, uniform display quality over the entire screen may be achieved without deteriorating image quality in the deformable section C such as a folding section, a bending section, or a rolling section.

Unlike the deformable section C, the non-deformable section NC of the stretchable display panel 2000 may not include a separate stretchable region 1000-2 and may include the non-stretchable region 1000-1. Accordingly, the non-deformable section NC of the stretchable display panel 2000 may be covered with the non-stretchable pattern 110b on the stretchable substrate 110a, and the whole non-deformable section NC may be covered with, for example, a plate-shaped non-stretchable pattern 110b.

As described above, the stretchable display panel 2000 according to some embodiments is manufactured, as described above, by disposing the stretchable region 1000-2 in the deformable section C such as a folding section, a bending section, or a rolling section to effectively reduce stress applied when repetitively folded, bent, or rolled and thus prevent or reduce damage in the deformable section C. In addition, this reduction of the stress applied in the deformable section C may realize a foldable, bendable, or rollable display panel with a small curvature, for example, less than or equal to about 1 mm, less than or equal to about 0.8 mm, less than or equal to about 0.5 mm, less than or equal to about 0.3 mm, less than or equal to about 0.2 mm, or less than or equal to about 0.1 mm.

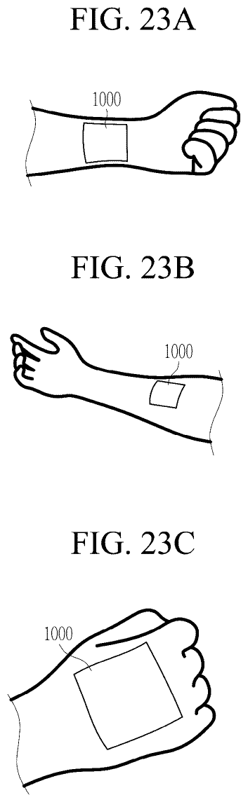

FIG. 23 is a schematic view illustrating a skin-type sensor array according to at least one example.

Referring to FIG. 23, the skin-type sensor array 3000 according to an example may be an attachable biometric sensor array, and may include the aforementioned stretchable panel 1000. The skin-type sensor array 3000 may be attached to a biological surface such as skin, a living body such as an organ, or an indirect means contacting a living body such as clothes to sense and measure biological information such as a biological signal. For example, the biosensor array includes an electroencephalogram (EEG) sensor, an electrocardiogram (ECG) sensor, a blood pressure (BP) sensor, an electromyography (EMG) sensor, a blood glucose (BG) sensor, a photoplethysmography (PPG) sensor, an accelerometer, a RFID antenna, an inertial sensor, an activity sensor, a strain sensor, a motion sensor, and/or a combination thereof, but is not limited thereto. The skin-type sensor array 3000 may also be referred to as a biosensor. The biosensor array 3000 may be attached to a living body in a very thin patch type or band type to monitor biometric information in real time. For example, the skin-type sensor array 3000 may be a sensor array including a photo blood flow measurement sensor (PPG sensor), and the biometric information may include heart rate, oxygen saturation, stress, arrhythmia, blood pressure, etc., and biometric information may be obtained by analyzing the waveform of an electrical signal.

The aforementioned stretchable panel 1000 and the stretchable display panel 2000 or the biosensor array 3000 including the stretchable panel 1000 may be included in various electronic devices, and the electronic device may further include a processor (not shown) and a memory (not shown).

The electronic devices may include, for example, mobile phones, video phones, smart phones, smart pads, smart watches, digital cameras, tablet PCs, laptop PCs, notebook computers, computer monitors, wearable computers, televisions, digital broadcasting terminals, e-books, and personal digital assistants (PDAs), PMP (portable multimedia player), EDA (enterprise digital assistant), head mounted displays (HMD), in-vehicle navigations, Internet of Things (IoT), Internet of Everything (IoE), security devices, medical devices, but are not limited thereto.

Hereinafter, the embodiments are illustrated in more detail with reference to examples. However, these examples are exemplary, and the present scope is not limited thereto.

### EXAMPLES

### Example 1

Silver (Ag) is thermally deposited on a polyethyleneterephthalate (PET) substrate to form a 100 nm-thick first conductive layer. Subsequently, a styrene-ethylene-butylene-styrene (SEBS) solution is coated on the first conductive layer and then, annealed at 120° C. for 60 minutes to form a 20 nm-thick elastic layer. On the elastic layer, Au is thermally deposited at 0.1 Å/s to form a 75 nm-thick second conductive layer and thus, prepare an electrode.

### Example 2

A styrene-ethylene-butylene-styrene (SEBS) solution is coated on a polyethyleneterephthalate (PET) substrate and then, annealed at 120° C. for 60 minutes to form a 20 nm-thick elastic layer, and Au is thermally deposited thereon at 0.1 Å/s to form a 75 nm-thick second conductive layer. Subsequently, on the second conductive layer, silver (Ag) is thermally deposited to form a 100 nm-thick first conductive layer, preparing an electrode.

### Reference Example 1

On a polyethyleneterephthalate (PET) substrate, silver (Ag) is thermally deposited to prepare a 100 nm-thick electrode.

### Reference Example 2

On a polyethyleneterephthalate (PET) substrate, a styrene-ethylene-butylene-styrene (SEBS) solution is coated and then, annealed at 120° C. for 60 minutes to form a 20 nm-thick elastic layer, and Au is thermally deposited thereon at 0.1 Å/s to form a 75 nm-thick electrode.

### Evaluation I

The electrodes according to Examples and Reference Examples are evaluated with respect to electrical conductivity.

The electrical conductivity is measured at a Probe station by using an inductance-capacitance-resistance (LCR) meter made by TI (Texas Instruments Inc.).

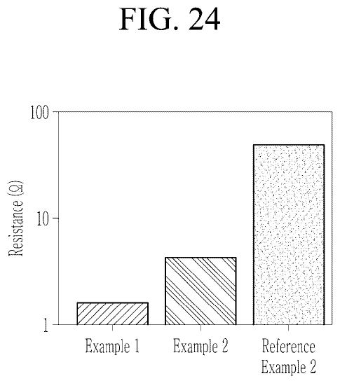

The results are shown in FIG. 24.

FIG. 24 is a graph showing electrical conductivity of the electrodes according to Examples and Reference Examples.

Referring to FIG. 24, the electrodes according to Examples, compared with the electrodes according to Reference Examples, exhibit improved electrical conductivity.

### Evaluation II

Electrical characteristics according to stretching of the electrodes of Examples and Reference Examples are evaluated.

The electrical characteristics according to stretching are evaluated by measuring a change in resistance, while repeatedly 2000 times bending the electrodes according to Examples and Reference Examples.

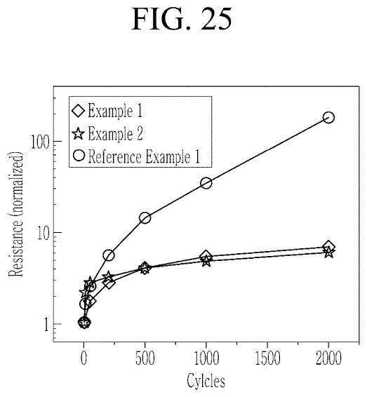

The results are shown in FIG. 25.

FIG. 25 is a graph showing electrical characteristics according to stretching of the electrodes according to Examples and Reference Examples.

Referring to FIG. 25, the electrical characteristics after 2000 times stretching the electrodes according to Example, compared with of the electrodes according to Reference examples, exhibit high stretching stability.

While this disclosure has been described in connection with what is presently considered to be practical example embodiments, it is to be understood that the inventive concepts are not limited to the disclosed embodiments. On the contrary, it is intended to cover various modifications and equivalent arrangements included within the spirit and scope of the appended claims.

What is claimed is:

1. A stretchable panel, comprising
a stretchable substrate; and
a wire electrode on the stretchable substrate, the wire electrode comprising
a first conductive layer comprising a first conductor,
an elastic layer, and
a second conductive layer on the elastic layer and comprising a second conductor.

2. The stretchable panel of claim 1, wherein the elastic layer comprises an elastomer and the second conductor.

3. The stretchable panel of claim 2, wherein the second conductor included in the elastic layer is unevenly distributed along a thickness direction of the elastic layer.

4. The stretchable panel of claim 3, wherein
the elastic layer comprises a first region relatively close to the second conductive layer and a second region relatively distant from the second conductive layer along the thickness direction of the elastic layer, and
a distribution of the second conductor included in the first region is greater than a distribution of the second conductor included in the second region.

5. The stretchable panel of claim 1, wherein the first conductive layer and the second conductive layer are electrically connected.

6. The stretchable panel of claim 1, further comprising:
a non-stretchable pattern covering a portion of the stretchable substrate, the non-stretchable pattern having a higher elastic modulus than the stretchable substrate,
a plurality of unit elements on the non-stretchable pattern, and
a plurality of pixel circuits configured to independently operate the plurality of unit elements.

7. The stretchable panel of claim 6, wherein the non-stretchable pattern comprises
a plurality of planar patterns repeatedly arranged on the stretchable substrate and on which the plurality of unit elements are arranged, and
a plurality of bridge patterns connecting adjacent planar patterns,
wherein the wire electrode is on the plurality of planar patterns and the plurality of bridge patterns.

8. The stretchable panel of claim 7, wherein the wire electrode electrically connects the plurality of unit elements and/or electrically connects the unit elements and the pixel circuits.

9. The stretchable panel of claim 6, wherein
the non-stretchable pattern comprises a plurality of island-shaped patterns repeatedly arranged on the stretchable substrate and separated from each other,
each of the plurality of unit elements is on a respective one of the plurality of island-shaped patterns, and
the wire electrode electrically connects adjacent unit elements of the plurality of unit elements between adjacent ones of the plurality of island-shaped patterns.

10. The stretchable panel of claim 9, further comprising
a non-stretchable layer positioned at least under or on the wire electrode.

11. The stretchable panel of claim 6, wherein the non-stretchable pattern comprises polycarbonate, polymethylmethacrylate, polyethyleneterephthalate, polyethylenenaphthalate, polyimide, polyamide, polyamideimide, polyethersulfone, or a combination thereof.

12. The stretchable panel of claim 6, wherein the plurality of unit elements comprise a light emitting diode, a photoelectric conversion diode, or a combination thereof.

13. The stretchable panel of claim 6, wherein
the plurality of pixel circuits includes a first pixel circuit and a second pixel circuit for each of the plurality of unit elements,
the first pixel circuit is on the non-stretchable pattern, and
the second pixel circuit is on the stretchable substrate that is not covered by the non-stretchable pattern.

14. The stretchable panel of claim 1, wherein the first conductive layer, the elastic layer, and the second conductive layer are sequentially stacked from the stretchable substrate.

15. The stretchable panel of claim 14, wherein a width of the second conductive layer is greater than a width of the elastic layer.

16. The stretchable panel of claim 14, wherein at least a portion of the second conductive layer is in direct contact with the first conductive layer.

17. The stretchable panel of claim 1, wherein the elastic layer, the second conductive layer, and the first conductive layer are sequentially stacked from the stretchable substrate.

18. The stretchable panel of claim 1, wherein the first conductor and the second conductor comprise each independently silver (Ag), gold (Au), copper (Cu), aluminum (Al), nickel (Ni), molybdenum (Mo), an alloy thereof, or a combination thereof.

19. The stretchable panel of claim 1, wherein the elastic layer comprises at least one of polyorganosiloxane, a polymer comprising a butadiene structural unit, a polymer comprising an olefin structural unit, a polymer comprising a urethane structural unit, a polymer comprising an acrylic structural unit, or a combination thereof.

20. An electronic device comprising the stretchable panel of claim 1.
